(19) United States
(12) Patent Application Publication
(10) Pub. No.: US 2020/0219805 A1
(43) Pub. Date: Jul. 9, 2020

(54) DISPLAY TRACE STRUCTURE AND DISPLAY PANEL STRUCTURE THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jinxue WENG, Wuhan, Hubei (CN)

(21) Appl. No.: 16/613,435

(22) PCT Filed: Feb. 15, 2019
(86) PCT No.: PCT/CN2019/075168

§ 371 Date: Nov. 14, 2019

(30) Foreign Application Priority Data
Dec. 12, 2018 (CN) 201811518876.X

(51) Int. Cl. H01L 23/528

(52) U.S. Cl. CPC H01L 23/528; H01L 27/15

(57) ABSTRACT

A display trace structure and a display panel structure thereof are provided. The display trace structure includes a display area, a bending area, a component disposing area, and a plurality of traces distributed from the display area to the component disposing area across the bending area, wherein at least one of the plurality of traces has a first opening region and a second opening region overlapping each other. The traces are provided with a plurality of opening regions overlapping each other to prevent cracks from penetrating the traces, thereby increasing product yield.

### FIELD OF INVENTION

The present invention relates to a display trace structure, and more particularly to a trace structure for a flexible display.

### BACKGROUND OF INVENTION

In recent years, display devices have moved toward higher screen ratios and higher resolutions, and narrow bezels have become a trend in development of display device structures. Regarding flexible light emitting diode displays, current structures generally bend a controller chip disposing area to a back side of a panel, to reduce an area occupied by a bezel. Because the bending radius is small, traces disposed at the bending area is subjected to large stress, which causes the trace prone to breakage, so there is a great impact on product yield.

Therefore, it is necessary to provide a display trace structure to solve the problems existing in the conventional art.

### Technical Problem

Regarding the flexible light emitting diode displays, the current structures generally bend a controller chip disposing area to a back side of a panel, so as to reduce an area occupied by a bezel. Because the bending radius is small, the traces disposed at the bending area is subjected to large stress, which causes the trace prone to breakage, so there is a great impact on the product yield.

Therefore, it is necessary to provide a display trace structure to solve the problems existing in the conventional art.

### SUMMARY OF INVENTION

In view of above, the present invention provides a display trace structure to solve the problem existing in the conventional art that the traces disposed at the bending area is subjected to large stress, which causes the trace to be prone to breakage, so there is a great impact on the product yield.

A primary object of the present invention is to provide a display trace structure that can improve the problem that a flexible light emitting diode display cracks because of bending.

A secondary object of the present invention is to provide a display trace structure which may provide a plurality of overlapping opening regions, such that the plurality of overlapping opening regions can effectively prevent the crack from extending, so as to prevent the crack from running through the traces and causing the product failure, thereby increasing the product yield.

In order to achieve the foregoing objects of the present invention, an embodiment of the present invention provides a display trace structure including: a display area, a bending area and a component disposing area; and a plurality of traces distributed from the display area to the component disposing area across the bending area, wherein at least one of the plurality of traces has a plurality of circular openings, the plurality of circular openings include a first circular opening region and a second circular opening region overlapping each other, and wherein the plurality of openings have a first row of openings and a second row of openings disposed side by side.

In an embodiment of the present invention, an extension line connected between a center of the first opening region and a center of the second opening region is parallel to an extension direction of the at least one trace.

In an embodiment of the present invention, a connecting line of centers of the first row of openings is parallel to a connecting line of centers of the second row of openings.

In an embodiment of the present invention, the first row of openings and the second row of openings are disposed to stagger each other.

In an embodiment of the present invention, a first projection of the first row of openings in a direction laterally perpendicular to an extension direction of the at least one trace is partially overlapping with a second projection of the second row of openings in a direction laterally perpendicular to the extension direction.

In an embodiment of the present invention, a first projection of the first row of openings in the direction laterally perpendicular to the extension direction of the at least one trace is partially overlapping with the second projection of the second row of openings in a direction laterally perpendicular to the extension direction.

In an embodiment of the present invention, a first distance is defined between the first row of openings and an edge of the at least one trace; a second distance is defined between the second row of openings distanced and the other edge of the at least one trace, and the first distance is equal to the second distance.

Moreover, another embodiment of the present invention further provides a display trace structure including:

a display area, a bending area and a component disposing area; and

a plurality of traces distributed from the display area to the component disposing area across the bending area,

wherein at least one of the plurality of traces has a plurality of openings, the plurality of openings having a first opening region and a second opening region overlapping each other.

In an embodiment of the present invention, the first opening region and the second opening region are both circular.

In an embodiment of the present invention, an extension line connected between a center of the first opening region and a center of the second opening region is parallel to an extension direction of the at least one trace.

In an embodiment of the present invention, the plurality of openings have a first row of openings and a second row of openings disposed side by side.

In an embodiment of the present invention, a connecting line of centers of the first row of openings is parallel to a connecting line of centers of the second row of openings.

In an embodiment of the present invention, the first row of openings and the second row of openings are disposed to stagger each other.

In an embodiment of the present invention, a first projection of the first row of openings in a direction laterally perpendicular to an extension direction of the at least one trace is partially overlapping with a second projection of the second row of openings in a direction laterally perpendicular to the extension direction.

In an embodiment of the present invention, a first projection of the first row of openings in the direction laterally perpendicular to the extension direction of the at least one trace is partially overlapping with the second projection of the second row of openings in a direction laterally perpendicular to the extension direction.

In an embodiment of the present invention, a first distance is defined between the first row of openings and an edge of the at least one trace; a second distance is defined between the second row of openings and the other edge of the at least one trace, and the first distance is equal to the second distance.

Furthermore, yet another embodiment of the present invention provides a display panel structure including:

a plurality of traces distributed from a display area to a component disposing area across a bending area,

wherein at least one of the plurality of traces has a plurality of openings, and the plurality of openings have a first opening region and a second opening region overlapping each other.

In an embodiment of the present invention, wherein the first opening region and the second opening region are both circular.

In an embodiment of the present invention, wherein an extension line connected between a center of the first opening region and a center of the second opening region is parallel to an extension direction of the at least one trace.

In an embodiment of the present invention, wherein the plurality of openings have a first row of openings and a second row of openings disposed side by side.

### Beneficial Effect

Compared with the conventional art, the display trace structure of the present invention can not only improve problem that a crack run through a trace so the product is failure, but also be able to stop the crack from continuing to expend after the crack expended into the opening, thereby avoiding trace breakage, so as to improve product yield.

### DRAWINGS

In order to make the above description of the present invention more comprehensible, the preferred embodiments are described below, and in conjunction with the accompanying drawings, the detailed description is as follows:

FIG. 1 is a schematic view of a display trace structure according to a first embodiment of the present invention.

FIG. 1A is an enlarged schematic view of an opening structure of a second power supply trace of FIG. 1 at 1A.

FIG. 2 is a schematic view of the display trace structure cracked due to stress according to the first embodiment of the present invention.

FIG. 3 is a schematic view of a display trace structure according to a second embodiment of the present invention.

### DETAILED DESCRIPTION OF EMBODIMENTS

The following description of the various embodiments is provided to illustrate the specific embodiments of the invention. Furthermore, the directional terms mentioned in the present invention, such as upper, lower, top, bottom, front, rear, left, right, inner, outer, side, surrounding, central, horizontal, horizontal, vertical, longitudinal, axial, radial, uppermost or lowermost, etc., only refer to the direction of the additional schema. Therefore, the directional terminology used is for the purpose of illustration and understanding of the invention.

In order to achieve the foregoing object of the present invention, the present invention provides a display trace structure including: a trace having a plurality of openings, the plurality of openings having a first opening region and a second opening region overlapping each other. Optionally, the first opening region and the second opening region are both circular. Optionally, an extension line connected between a center of the first opening region and a center of the second opening region is parallel to an extension direction of the at least one trace. Optionally, the plurality of openings have a first row of openings and a second row of openings disposed side by side. Optionally, a connecting line of centers of the first row of openings is parallel to a connecting line of centers of the second row of openings. Optionally, the first row of openings and the second row of openings are disposed to stagger each other. Optionally, a first projection of the first row of openings in a direction laterally perpendicular to an extension direction of the at least one trace is partially overlapping with a second projection of the second row of openings in a direction laterally perpendicular to the extension direction. Optionally, a first projection of the first row of openings in the direction laterally perpendicular to the extension direction of the at least one trace is partially overlapping with the second projection of the second row of openings in a direction laterally perpendicular to the extension direction. Optionally, a first distance is defined between the first row of openings and an edge of the at least one trace; a second distance is defined between the second row of openings and the other edge of the at least one trace, and the first distance is equal to the second distance.

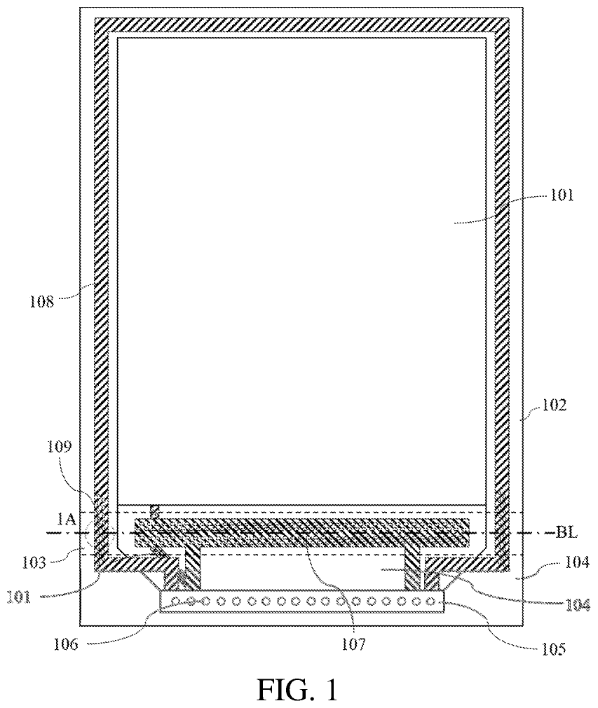

Referring to FIG. 1, FIG. 1 illustrates a display trace structure according to a first embodiment of the present invention, the display trace structure includes: a display area 101, a non-display area 102, a bending area 103, a component disposing area 104, and a plurality of traces. The non-display area 102 is distributed around the display area 101, and is bilaterally symmetrical, and sequentially extends downward to form the bending area 103. The component disposing area 104 is disposed under the display area 101, and is configured for disposed the traces and a chip 105. The chip 105 is, for example, a controller chip. The component disposing region 104 has a plurality of component connection interfaces 106 connected with the controller chip 105. The component disposing area 104 is provided with a fan-out routing area, and the fan-out routing area is provided with a plurality of data lines 110, which are passing through the bending area 103 and the fan-out routing area, so as to control the display area 101 by the controller chip 105. Furthermore, the component disposing area 104 is further provided with a first power line 107, disposed under the display area 101 and connected to the component connection interfaces 106. Preferably, the first power line 107 is a high potential power line to provide a high potential voltage to the display area 101. The display area 101 has a second power line 108 around the display area 101 and extends downwardly around the periphery of the first power line 107 and extends downwardly to connected to the component connection interfaces 106. Preferably, the second power line 108 is a low potential power line. The first power line and the second power line are arranged side by side in two rows, and are parallel to each other. The bending area 103 is disposed between the display area 101 and the component disposing area 104, and is bendable along a line BL. Optionally, the traces may be the data line 110, the first power line 107, and the second power line 108, across from the display area 101 via the bending area 103 to the component disposing area, at least one of the traces has a plurality of openings 109, the openings 109 have a first opening region and a second opening region overlapping each other. When the bending area 103 is bent along the BL line, the openings 109 may disperse stress to prevent the trace from cracking. Optionally, the openings 109 may be disposed on the data line 110, the first power line 107, the second power line 108, and a combination thereof. Alternatively, the openings 109 may only be disposed in a portion of the traces located in the bending area 103.

Referring to FIG. 1A, FIG. 1A illustrates an enlarged schematic view of the opening structure of the second power line of FIG. 1. In this embodiment, the openings 109 are disposed in the second power line 108, and the openings 109 have a first opening region 109A and a second opening region 109B overlapping each other. The first opening region 109A and the second opening region 109B are both circular. An extension line connected between a center of the first opening region 109A and a center of the second opening region 109B is parallel to an extension direction of the at least one trace. The openings have a first row of openings and a second row of openings disposed side by side. A connecting line L1 of centers of the first row of openings is parallel to a connecting line L2 of centers of the second row of openings. Preferably, the first row of openings and the second row of openings are disposed to stagger each other. Optionally, a first projection of the first row of openings in a direction laterally perpendicular to an extension direction of the at least one trace is partially overlapping with a second projection of the second row of openings in a direction laterally perpendicular to the extension direction. A first projection of the first row of openings in the direction laterally perpendicular to the extension direction of the at least one trace is partially overlapping with the second projection of the second row of openings in a direction laterally perpendicular to the extension direction. A first distance d1 is defined between the first row of openings and an edge of the at least one trace; a second distance d2 is defined between the second row of openings and the other edge of the at least one trace, and the first distance d1 is equal to the second distance d2.

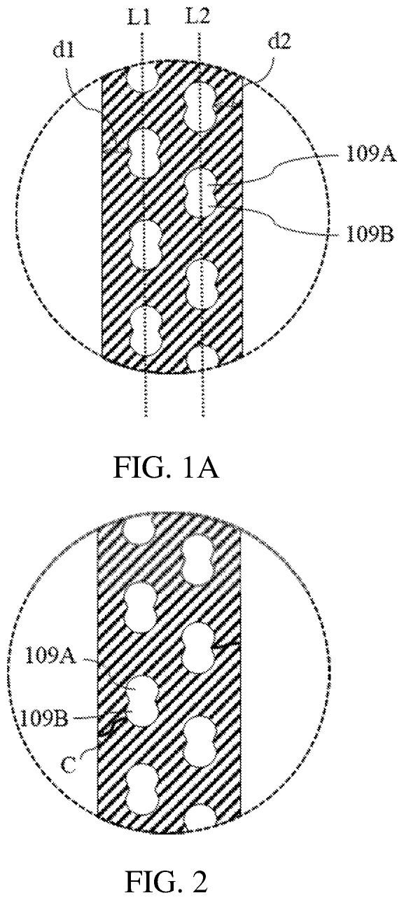

Referring to FIG. 2, when the at least one of the traces causes a crack C due to a stress. In general, in a case that the crack C continues to expand under a continuous action of the stress, and even results in breakage of the trace, so as to cause product failure. The first opening region 109A and the second opening region 109B overlapping each other according to the present invention can effectively prevent the expansion of the crack C. When the crack C expends to the first opening region 109A or the second opening region 109B, it is blocked by the first opening region 109A or the second opening region 109B, and cannot continue to expand. According to the study result of the inventor of the present invention, the structure of the overlapping opening regions in one opening is significantly superior to a single-opening region structure in one opening.

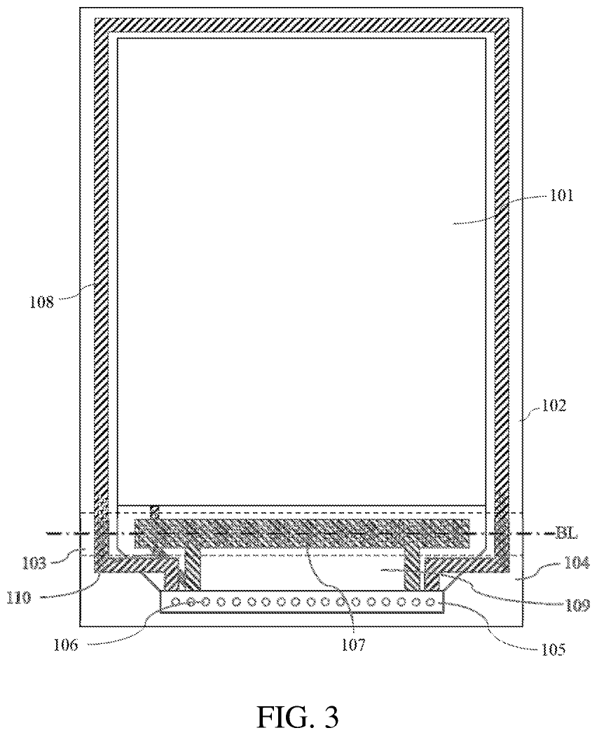

Referring to FIG. 3, FIG. 3 illustrates a display trace structure according to a second embodiment of the present invention. The second embodiment is similar to the first embodiment, the difference is that: a direction of the openings in the first power line is different from the direction of the openings in the first power line of the first embodiment.

The invention further provides a display panel structure having a plurality of traces. The traces include a display trace structure as described above.

As described above, compared with the existing display trace structure, the existing trace in the bending area is subject to large stress, which causes the trace to be prone to breakage and affect the product yield. The display trace structure according to the present invention can prevent crack from expending by effectively providing a plurality of overlapping opening regions in the trace, so as to prevent cracks from penetrating through the trace, causing trace breakage and product failure. So the product yield can increase, and the product performance and quality can improve.

The present invention has been described by the above related embodiments, but the above embodiments are merely examples for implementing the present invention. It must be noted that the disclosed embodiments do not limit the scope of the invention. Rather, modifications and equivalent arrangements are intended to be included within the scope of the invention.

1. A display trace structure, comprising:
a display area, a bending area, and a component disposing area; and
a plurality of traces distributed from the display area to the component disposing area across the bending area,
wherein at least one of the plurality of traces has a plurality of circular openings, the plurality of circular openings include a first circular opening region and a second circular opening region overlapping each other, and
wherein the plurality of circular openings have a first row of openings and a second row of openings disposed side by side.

2. The display trace structure according to claim 1, wherein an extension line connected between a center of the first circular opening region and a center of the second circular opening region is parallel to an extension direction of the at least one trace.

3. The display trace structure according to claim 1, wherein a connecting line of centers of the first row of openings is parallel to a connecting line of centers of the second row of openings.

4. The display trace structure according to claim 3, wherein the first row of openings and the second row of openings are disposed to stagger each other.

5. The display trace structure according to claim 3, wherein a first projection of the first row of openings in a direction laterally perpendicular to an extension direction of the at least one trace is partially overlapping with a second projection of the second row of openings in a direction laterally perpendicular to the extension direction.

6. The display trace structure according to claim 4, wherein a third projection of two adjacent of the first row of openings in the direction laterally perpendicular to the extension direction of the at least one trace is partially overlapping with the second projection of the second row of openings in a direction laterally perpendicular to the extension direction.

7. The display trace structure according to claim 1, wherein a first distance is defined between the first row of openings and an edge of the at least one trace; a second distance is defined between the second row of openings distanced and the other edge of the at least one trace, and the first distance is equal to the second distance.

8. A display trace structure, comprising:
a display area, a bending area, and a component disposing area; and
a plurality of traces distributed from the display area to the component disposing area across the bending area,
wherein at least one of the plurality of traces has a plurality of openings, the plurality of openings having a first opening region and a second opening region overlapping each other.

9. The display trace structure according to claim 8, wherein the first opening region and the second opening region are both circular.

10. The display trace structure according to claim 8, wherein an extension line connected between a center of the first opening region and a center of the second opening region is parallel to an extension direction of the at least one trace.

11. The display trace structure according to claim 8, wherein the plurality of openings have a first row of openings and a second row of openings disposed side by side.

12. The display trace structure according to claim 11, wherein a connecting line of centers of the first row of openings is parallel to a connecting line of centers of the second row of openings.

13. The display trace structure according to claim 12, wherein the first row of openings and the second row of openings are disposed to stagger each other.

14. The display trace structure according to claim 12, wherein a first projection of the first row of openings in a direction laterally perpendicular to an extension direction of the at least one trace is partially overlapping with a second projection of the second row of openings in a direction laterally perpendicular to the extension direction.

15. The display trace structure according to claim 13, wherein a third projection of two adjacent of the first row of openings in the direction laterally perpendicular to the extension direction of the at least one trace is partially overlapping with the second projection of the second row of openings in a direction laterally perpendicular to the extension direction.

16. The display trace structure according to claim 11, wherein a first distance is defined between the first row of openings and an edge of the at least one trace; a second distance is defined between the second row of openings and the other edge of the at least one trace, and the first distance is equal to the second distance.

17. A display panel structure, comprising:
a plurality of traces distributed from a display area to a component disposing area across a bending area,
wherein at least one of the plurality of traces has a plurality of openings, and the plurality of openings have a first opening region and a second opening region overlapping each other.

18. The display panel structure according to claim 17, wherein the first opening region and the second opening region are both circular.

19. The display panel structure according to claim 17, wherein an extension line connected between a center of the first opening region and a center of the second opening region is parallel to an extension direction of the at least one trace.

20. The display panel structure according to claim 17, wherein the plurality of openings have a first row of openings and a second row of openings disposed side by side.
